(19) United States
(12) Patent Application Publication
(10) Pub. No.: US 2025/0196896 A1
(43) Pub. Date: Jun. 19, 2025

(54) Article Transport Facility

(71) Applicant: Daifuku Co., Ltd., Osaka-shi (JP)

(72) Inventors: Makoto Kono, Komaki-shi (JP); Koichi Hagiwara, Komaki-shi (JP)

(21) Appl. No.: 18/980,971

(22) Filed: Dec. 13, 2024

(30) Foreign Application Priority Data
Dec. 14, 2023 (JP) 2023-211370

(51) Int. Cl. B61B 3/02

(52) U.S. Cl. CPC B61B 3/02

(57) ABSTRACT

An article transport facility includes a control system. The control system is configured to perform an entry permission issuing process of giving an entry permission to allow a plurality of transport vehicles to enter a junction, based on a cost calculated as a factor influencing a travel time of the transport vehicles in each of two pre-junction sections which cost increases as the travel time is longer, in such a manner as to give the entry permission to more entry-waiting transport vehicles in first a pre-junction section for which the cost is larger out of the two pre-junction sections than in a second pre-junction section for which the cost is smaller out of the two pre-junction sections.

### CROSS-REFERENCE TO RELATED APPLICATION

This application claims priority to Japanese Patent Application No. 2023-211370 filed Dec. 14, 2023, the disclosure of which is hereby incorporated by reference in its entirety.

### BACKGROUND OF THE INVENTION

### 1. Field of the Invention

The present invention relates to an article transport facility including a plurality of transport vehicles moving along a predetermined path.

### 2. Description of Related Art

Japanese Unexamined Patent Application Publication No. 2018-128914 (JP 2018-128914) discloses an example of the article transport facility. In the article transport facility of JP 2018-128914, a first stop position (P3) and a second stop position (P4) are set on the upstream side from a junction position (P2), and a transport vehicle (3) entering a pre-junction section including the second stop position (P4), for example, waits at the second stop position (P4) until the transport vehicle (3) is allowed to enter a junction including the junction position (P2).

In the article transport facility of JP 2018-128914, even when a great number of transport vehicles stop in the pre-junction section including the second stop position, transport vehicles stopping in a pre-junction section including the first stop position and the transport vehicles stopping in the pre-junction section including the second stop position are allowed to enter the junction on the same condition. Accordingly, an uneven state where the number of transport vehicles stopping in the pre-junction section including the second stop position is large continues, and transport vehicles that cannot enter the pre-junction section including the second stop position might cause a traffic jam in a section on the upstream side from the pre-junction section. Such a traffic jam might cause a decrease in article transport efficiency in the whole article transport facility.

### SUMMARY OF THE INVENTION

In view of the foregoing, an article transport facility that easily restrains the occurrence of a traffic jam in a section on the upstream side from a pre-junction section is desired.

An article transport facility according to this disclosure includes: a plurality of transport vehicles each configured to move along a predetermined path and transport an article; and a control system configured to control the plurality of transport vehicles. The path includes a junction at which two pre-junction sections are merged into one post-junction section. The control system is configured to perform an entry permission issuing process of giving an entry permission to allow the plurality of transport vehicles to enter the junction, based on a cost calculated as a factor influencing a travel time of the transport vehicles in each of the two pre-junction sections which cost increases as the travel time is longer, in such a manner as to give the entry permission to more entry-waiting transport vehicles in a first pre-junction section for which the cost is larger out of the two pre-junction sections than in a second pre-junction section for which the cost is smaller out of the two pre-junction sections, the entry-waiting transport vehicles being transport vehicles waiting for entering the junction.

With this configuration, a larger number of transport vehicles in a pre-junction section that requires a longer travel time for the transport vehicles out of the two pre-junction sections preferentially receive the entry permission to enter the junction, thereby making it possible to reduce inequality in the number of entry-waiting transport vehicles between the two pre-junction sections. This can easily reduce such a possibility that the number of entry-waiting transport vehicles in either of the pre-junction sections is too large, and this influences the movement of other transport vehicles in a section on the upstream side from the pre-junction section. This accordingly makes it possible to restrain the occurrence of a traffic jam in the section on the upstream side from the pre-junction section.

### BRIEF DESCRIPTION OF THE DRAWINGS

FIG. 1 is a schematic view illustrating an article transport facility according to the present embodiment;

FIG. 2 is a schematic view illustrating the transport vehicle in FIG. 1;

FIG. 3 is a schematic view to describe an entry permission issuing process in the transport facility of FIG. 1;

FIG. 4 is a schematic view illustrating a state subsequent to FIG. 3;

FIG. 5 is a schematic view illustrating a state subsequent to FIG. 4; and

FIG. 6 is a schematic view illustrating a state subsequent to FIG. 5.

### DESCRIPTION OF THE INVENTION

An embodiment of an article transport facility will be described below with reference to drawings.

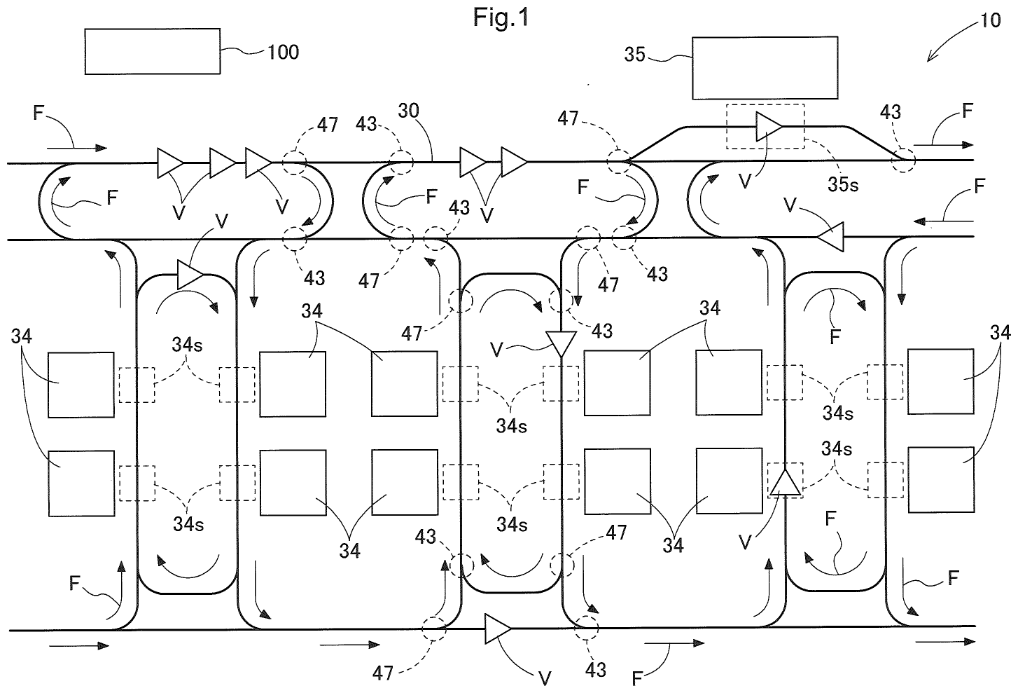

FIG. 1 is a view illustrating an example of an article transport facility 10 according to the present embodiment. As simply illustrated in FIG. 1, the article transport facility 10 includes a plurality of transport vehicles V each configured to move along a predetermined path 30 and transport an article U. The path 30 is a path (travel path) where the transport vehicle V is movable. The path 30 indicates a whole path on which the transport vehicle V travels. The path 30 is constituted by a set of a plurality of paths (partial paths).

The article transport facility 10 includes a control system 100 configured to control the plurality of transport vehicles V. Each function of the control system 100 is implemented by collaboration of hardware such as an arithmetic processing unit with a program executed on the hardware, for example. The whole control system 100 may be provided for the transport vehicle V, or part of the control system 100 may be provided for the transport vehicle V, and the other part of the control system 100 may be provided for an external control device (a control device provided outside the transport vehicle V and communicable with the transport vehicle V). The whole control system 100 may be provided for an external control device. Here, the external control device may not be one device and may be a set of a plurality of devices communicable with each other. The control system 100 controls traveling of each of the plurality of transport vehicles V to reach its destination. Examples of the “destination of a transport vehicle” include a station at a transport source (described later), a station at a transport destination, and the like.

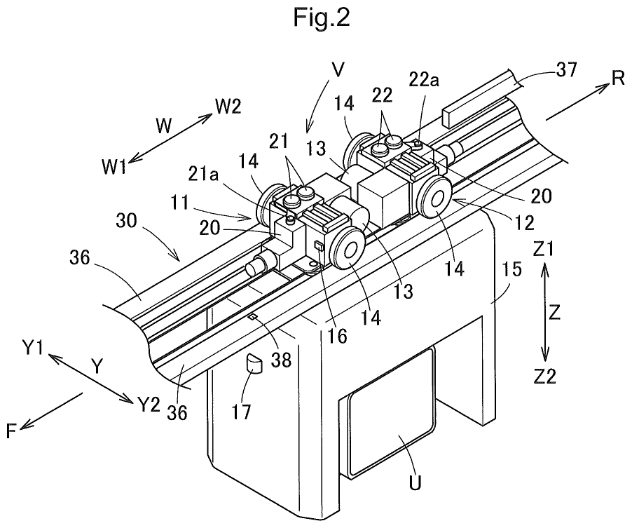

FIG. 2 is a view illustrating an example of the transport vehicle V. The transport vehicle V includes a controller (a device controller) configured to control a traveling drive unit 13 and a guide drive unit 20 (described later). In a case where at least part of the control system 100 is provided for an external control device, the controller of the transport vehicle V works in response to a command from the external control device. In a case where at least part of the control system 100 is provided for the transport vehicle V, the controller of the transport vehicle V may constitute the at least part of the control system 100.

As illustrated in FIG. 2, a direction along the path 30 is defined a travel direction W, and a direction (herein, a horizontal direction perpendicular to the travel direction W) perpendicular to the travel direction W as viewed vertically along an up-down direction Z (vertical direction) is defined as a width direction Y. As illustrated in FIG. 1, each portion of the path 30 has a forward direction F. A direction opposite from the forward direction F is defined as a reverse direction R (see FIG. 2), and the transport vehicle V basically travels in the forward direction F on the path 30. In the present embodiment, the path 30 allows the transport vehicle V to travel in the forward direction F to circulate between the transport source and the transport destination of the article U.

As illustrated in FIG. 2, a side toward the forward direction F along the path 30 is defined as a downstream side W1, and a side toward the reverse direction R along the path 30 is defined as an upstream side W2. The travel direction W can be rephrased as a front-rear direction of the transport vehicle V, the downstream side W1 can be rephrased as a front side of the transport vehicle V, and the upstream side W2 can be rephrased as a rear side of the transport vehicle V. One side (herein, the right side when the transport vehicle V faces the forward direction F) in the width direction Y is defined as a first side Y1 in the width direction, and the other side (herein, the left side when the transport vehicle V faces the forward direction F) in the width direction Y is defined as a second side Y2 in the width direction.

The transport vehicle V travels along the path 30 and transports the article U. The article U is, for example, a FOUP (Front Opening Unified Pod) storing a semiconductor wafer. The transport vehicle V is an unmanned transport vehicle. The transport vehicle V may include wheels or may not include wheels. The path 30 may be formed physically or may be formed virtually. In the present embodiment, the path 30 is physically formed of traveling rails 36 (a pair of traveling rails 36 disposed at an interval in the width direction Y). The traveling rails 36 are supported in such a manner as to hang from a ceiling, for example.

FIG. 2 assumes a case where the path 30 is formed along the ceiling, but the path 30 may be formed on a floor face or the like. In a case where the path 30 is formed on a floor face, the path 30 is physically formed of rails or a passage provided on the floor face, for example, or the path 30 is virtually formed of a two-dimensions code, an RF (Radio Frequency) tag, a magnetic tape, or the like provided on the floor face. The path 30 may be a path calculated based on a result of recognition of the environment around the transport vehicle V. Note that the floor face may be a floor face supported in such a manner as to hang from the ceiling.

As illustrated in FIG. 2, the transport vehicle V includes a first travel unit 11 as a travel unit. The first travel unit 11 includes travel wheels 14 configured to roll on travel surfaces (herein, surfaces facing the upper side Z1) of the traveling rails 36, and a traveling drive unit 13 (an electric motor such as a servomotor, for example) configured to rotate the travel wheels 14. When the travel wheels 14 are rotated by the traveling drive unit 13, the first travel unit 11 travels along the traveling rails 36. In the present embodiment, the transport vehicle V further includes a second travel unit 12 on the upstream side W2 relative to the first travel unit 11. The second travel unit 12 is configured similarly to the first travel unit 11 and travels along the traveling rails 36 in response to the travel wheels 14 rotated by the traveling drive unit 13.

The transport vehicle V includes a main body 15 connected to the first travel unit 11. The article U is stored in the main body 15 and transported by the transport vehicle V. In the present embodiment, the main body 15 is disposed on the lower side Z2 relative to the first travel unit 11 and supported by the first travel unit 11. In the present embodiment, the main body 15 is connected to both the first travel unit 11 and the second travel unit 12. The main body 15 is disposed on the lower side Z2 relative to the first travel unit 11 and the second travel unit 12 and supported by the first travel unit 11 and the second travel unit 12.

In the example illustrated in FIG. 2, the transport vehicle V includes a collision prevention sensor 17 configured to detect another transport vehicle V present on the downstream side W1 relative to the transport vehicle V. When the collision prevention sensor 17 detects another transport vehicle V, the transport vehicle V including the collision prevention sensor 17 decelerates or stops to avoid a collision with the another transport vehicle V.

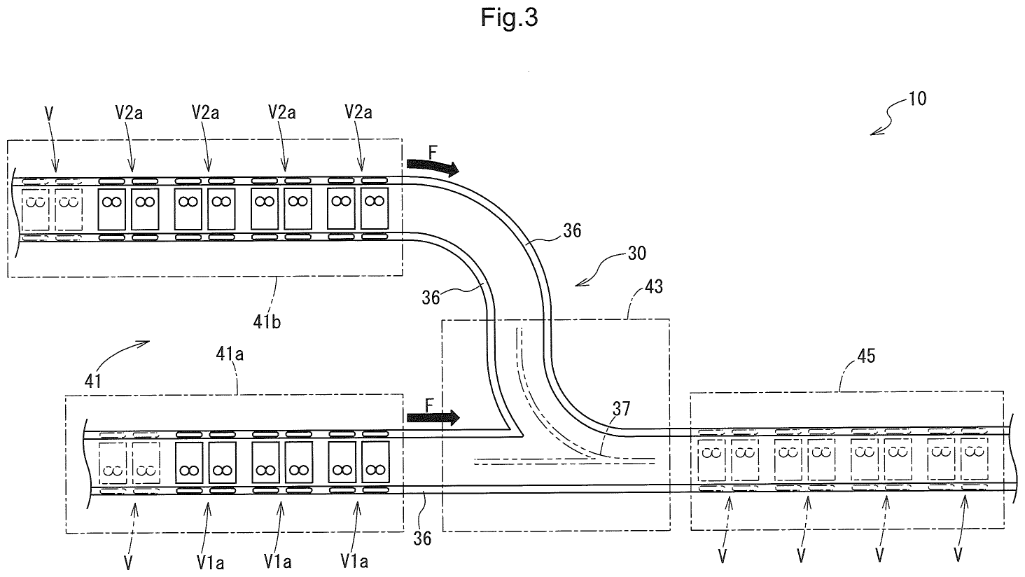

As illustrated in FIG. 2, in the present embodiment, information retainers 38 such as a two-dimensional code or an RF tag are provided at a plurality of points on the path 30. The information retainer 38 is provided, for example, at a point that can be a stop position for the transport vehicle V, e.g., a station (described later), a pre-junction section 41 (see FIG. 3), a post-junction section 45 (see FIG. 3), and the like. The information retainer 38 stores positional information as information indicative of the position where the information retainer 38 is provided. The transport vehicle V includes a reader 16 configured to read the positional information stored in the information retainer 38 and recognizes a current position of the transport vehicle V based on the positional information thus read by the reader 16. The transport vehicle V recognizes its current position, for example, based on the positional information read by the reader 16, and a travel distance after the reader 16 reads the positional information. The travel distance of the transport vehicle V is measured by use of a rotary encoder, for example. Note that the transport vehicle V can be configured to recognize its current position based on an output from a positioning device such as a GNSS (Global Navigation Satellite System) receiver.

The control system 100 grasps the current position of each of the plurality of transport vehicles V. In the present embodiment, the transport vehicle V is configured to recognize its current position in the manner described earlier, and the control system 100 grasps the current position of each of the plurality of transport vehicles V by acquiring, from the each of the plurality of transport vehicles V, information on the current position of the each of the plurality of the transport vehicles V. The control system 100 may be configured to grasp the number of entry-waiting transport vehicles Va (described later), the number of transport vehicles V in the pre-junction section 41, the number of transport vehicles V in the junction 43, or the number of transport vehicles V in the post-junction section 45 by acquiring, from each of the transport vehicles V, the information on the current position of the each of the transport vehicles V.

A plurality of stations each serving as a destination for the transport vehicle V is set on the path 30. The transport vehicle V transfers the article U to and from an article support provided in the station. The operation of the transport vehicle V includes a traveling operation to travel along the path 30, an operation to receive the article U from the article support in the station, and an operation to unload the article U to the article support in the station. After the transport vehicle V travels to a station of a transport source and receives the article U at the station, the transport vehicle V travels to a station of a transport destination and unloads the article U at the station.

Examples of the “article support” include a load port of a processing device 34 configured to perform machining, assortment, and the like on the article U, an inbound-outbound port of a storage device 35, a storage shelf (not illustrated) for temporarily storing the article U, and so on. The article support is placed right under the path 30 in a station, for example.

The “destination” of the transport vehicle V includes a processing-device station 34s for the transport vehicle V to transfer the article U to and from the processing device 34 (illustrated in FIG. 1) configured to perform processing on the article U. The “destination” of the transport vehicle V includes a storage-device station 35s for the transport vehicle V to transfer the article U to and from the storage device 35 (illustrated in FIG. 1) configured to store the article U. The destination of the transport vehicle V may include a maintenance station (not illustrated) for the transport vehicle V.

As illustrated in FIG. 2, a guide rail 37 is provided in some sections on the path 30. In the present embodiment, the guide rail 37 is disposed on the upper side Z1 relative to the traveling rails 36. In the present embodiment, the guide rail 37 is disposed, in the width direction Y, between the pair of the traveling rails 36 disposed at an interval in the width direction Y.

The transport vehicle V includes a guided section (21, 22) to be guided by the guide rail 37 in contact with the guide rail 37 from either side in the width direction Y, and a guide drive unit 20 (for example, a solenoid or an electric motor) configured to move the guided section in the width direction Y. The movement of the guided section in the width direction Y by the guide drive unit 20 is performed, for example, by driving only the guided section in the width direction Y, or by driving the guided section in the width direction Y together with a support for supporting the guided section.

In the present embodiment, the first travel unit 11 includes, as the guided section, a first guide wheel 21 configured to rotate (herein, freely move) around an axis along the up-down direction Z, and the guide drive unit 20 provided in the first travel unit 11 moves the first guide wheel 21 in the width direction Y. In the example illustrated in FIG. 2, the first travel unit 11 includes two first guide wheels 21 arranged in the travel direction W, and the guide drive unit 20 moves the two first guide wheels 21 in the width direction Y by moving a support supporting the two first guide wheels 21 in the width direction Y.

In the present embodiment, the second travel unit 12 includes, as the guided section, a second guide wheel 22 configured to rotate (herein, freely move) around an axis along the up-down direction Z, and the guide drive unit 20 provided in the second travel unit 12 moves the second guide wheel 22 in the width direction Y. In the example illustrated in FIG. 2, the second travel unit 12 includes two second guide wheels 22 arranged in the travel direction W, and the guide drive unit 20 moves the two second guide wheels 22 in the width direction Y by moving a support supporting the two second guide wheels 22 in the width direction Y. In the following description, in a case of describing common matters between the first guide wheel 21 and the second guide wheel 22, they are not distinguished from each other and will be collectively described as a “guide wheel.”

The transport vehicle V includes a movement detection unit configured to detect movement of the guide wheel in the width direction Y. In the present embodiment, the first guide wheel 21 and the second guide wheel 22 are guide wheels, and a first movement detection unit 21a and a second movement detection unit 21b are movement detection units. The control system 100 detects the movement of the guide wheel in the width direction Y by acquiring a detection result of the movement of the guide wheel in the width direction Y from the movement detection unit.

FIG. 3 is a view illustrating an example of the junction 43 provided for the path 30. The reverse direction R, the travel direction W, the downstream side W1, the upstream side W2, the width direction Y, the first side Y1 in the width direction, and the second side Y2 in the width direction are determined based on the forward direction F that is a travel direction to merge with the junction 43, and therefore, they are omitted in FIG. 3, and only the forward direction F is illustrated. The path 30 includes the junction 43 at which two pre-junction sections 41 are merged into one post-junction section 45. The path 30 includes a branch 47 (see FIG. 1) at which one pre-junction section branches into two post-junction sections.

The pre-junction section 41 is a section determined in advance for each junction 43. The two pre-junction sections 41 are part of the path 30 and each may be a single region. One or both of the two pre-junction sections 41 may be constituted by a plurality of regions. The pre-junction section 41 may include the post-junction section 45 on the upstream side W2 from the pre-junction section 41. In the present embodiment, the pre-junction section 41 is a section that does not include the junction 43 on the upstream side W2 from the pre-junction section 41. The pre-junction section 41 does not include other pre-junction sections 41. The pre-junction section 41 does not include the station. The pre-junction section 41 is a section including no guide rail 37. In the example illustrated herein, the pre-junction section 41 is a linear section.

The post-junction section 45 is a section determined in advance for each junction 43. The post-junction section 45 is part of the path 30 and may be a single region. The post-junction section 45 may be constituted by a plurality of regions. The post-junction section 45 may include the pre-junction section 41 on the downstream side W1 from the post-junction section 45. In the present embodiment, the post-junction section 45 is a section including no junction 43 on the downstream side W1 from the post-junction section 45. The post-junction section 45 does not include other post-junction sections 45. The post-junction section 45 does not include the station. The post-junction section 45 is a section including no guide rail 37. In the example illustrated herein, the post-junction section 45 is a straight section.

Here, the transport vehicles V waiting for entering the junction 43 in each of the two pre-junction sections 41 are referred to as the entry-waiting transport vehicles Va. Examples of the entry-waiting transport vehicle Va include a transport vehicle V stopping in the pre-junction section 41, a transport vehicle V traveling in the pre-junction section 41, and so on. The entry-waiting transport vehicles Va may include a transport vehicle V traveling in a section on the upstream side W2 from the pre-junction section 41. The entry-waiting transport vehicle Va is acquired by various sensors, an imaging device (not illustrated) configured to capture an image of the pre-junction section 41, image recognition, and the like, for example.

FIG. 3 illustrates a state right before an entry permission issuing process is performed. In a case where the control system 100 performs an entry permission issuing process of giving an entry permission to allow a plurality of transport vehicles V to enter the junction 43, the control system 100 calculates a cost C as a factor influencing a travel time T of the transport vehicles V in each of the two pre-junction sections 41 which cost C increases as the travel time T is longer. Then, the control system 100 gives the entry permission to more entry-waiting transport vehicles Va in the pre-junction section 41 with a larger cost C than in the pre-junction section 41 with a smaller cost C.

In the present embodiment, the cost C is calculated based on at least one of a length H1 of the pre-junction section 41, an upper limit H2 for the number of transport vehicles V that can wait in the pre-junction section 41, an upper limit H3 of traveling speed for the transport vehicles V in the pre-junction section 41, an average value H4 of traveling speeds of the transport vehicles V in the pre-junction section 41, a current value H5 of the number of transport vehicles V present in the pre-junction section 41, and a predicted value H6 of the number of transport vehicles V to be present in future in the pre-junction section 41. Note that the cost C may be calculated based on at least two or at least three of the length H1, the upper limit H2 for the number of transport vehicles V, the upper limit H3 of traveling speed, the average value H4 of traveling speeds, the current value H5 of the number of transport vehicles V, and the predicted value H6 of the number of transport vehicles V. In the present embodiment, the cost C is a value that increases as an expected or actual travel time T in the pre-junction section 41 is longer.

In the present embodiment, the cost C is set to decrease as the upper limit H2 for the number of transport vehicles V increases. The cost C may be set to decrease as the length H1 of the pre-junction section 41 is longer. This can easily restrain the occurrence of a traffic jam to be caused when the transport vehicles V on the upstream side W2 from the pre-junction section 41 cannot enter the pre-junction section 41.

In the present embodiment, the cost C is set to decrease as the upper limit H3 of traveling speed increases. The cost C is set to decrease as the average value H4 of traveling speeds increases. The cost C is set to increase as the current value H5 of the number of transport vehicles V increases. The cost C is set to increase as the predicted value H6 of the number of transport vehicles V increases.

In the example illustrated in FIG. 3, the upper limit H2 for the number of transport vehicles V that can wait in the pre-junction section 41a is four, and the upper limit H2 for the number of transport vehicles V that can wait in the pre-junction section 41b is five. The current value H5 of the number of transport vehicles V may be acquired periodically or may be acquired every time the entry permission issuing process is performed. Examples of the upper limit H3 of traveling speed include a limited speed set for each pre-junction section 41, an upper limit of traveling speed in past data, and so on. Examples of the predicted value H6 of the number of transport vehicles V include the number of transport vehicles V set to travel on a path passing the pre-junction section 41, a predictive number of transport vehicles V which predictive number is calculated based on past data in the pre-junction section 41, and so on.

The cost C may be a value calculated based on a current value H7 of the number of transport vehicles V that can enter the pre-junction section 41. In the present embodiment, the cost C is set to decrease as the current value H7 of the number of transport vehicles V increases. The current value H7 of the number of transport vehicles V is a value obtained by subtracting the current value H5 of the number of transport vehicles V from the upper limit H2 for the number of transport vehicles V, for example. In the example illustrated herein, the current value H7 of the number of transport vehicles V is indicated by the number of transport vehicles V illustrated by an alternate long and two short dashes line in the pre-junction section 41.

The cost C may be a value obtained by adding a traffic jam cost to a reference cost. Examples of the reference cost include a reference value based on the length H1 of the pre-junction section 41, the upper limit H3 of traveling speed for the transport vehicles V in the pre-junction section 41, the average value H4 of traveling speeds, and the like. Examples of the traffic jam cost include a correction value based on the upper limit H2 of the number of transport vehicles V, the current value H5 of the number of transport vehicles V, the predicted value H6 of the number of transport vehicles V, the current value H7 of the number of transport vehicles, and the like. The cost C may be a value obtained by dividing the length H1 by the upper limit H3 of traveling speed or the average value H4 of traveling speeds. The cost C is derived as length, time, the number of transport vehicles, or the like, for example.

The cost C may be a value obtained by multiplying a distance cost as a cost corresponding to the distance of a section (for example, the pre-junction section 41) to which the cost C is set, by a correct coefficient determined based on a driving condition for the transport vehicle V in the section. The distance cost is set to increase as the section to which the distance cost is set is longer, for example. The correct coefficient is set to increase in a case where the driving condition for the transport vehicles V in the section to which the correct coefficient is set is a condition that requires a longer time for the transport vehicles V to pass the section. Although not described specifically, the path 30 can be expressed by use of nodes and a link connecting the nodes to each other. The nodes correspond to specific spots such as the branch 47 and the junction 43, and the link corresponds to a path connecting the specific spots to each other. The cost C may be a cost of a section corresponding to a link, that is, a link cost. The pre-junction section 41 may be a link just before the junction 43 or may be a link on the upstream side W2 from the junction 43 which link is different from the link just before the junction 43. The pre-junction section 41 may be a single link or may be constituted by a plurality of links.

Here, the cost C of the pre-junction section 41 with a larger cost C is referred to as a first cost C1, and the cost C of the pre-junction section 41 with a smaller cost C is referred to as a second cost C2. The control system 100 provides an entry permission to the entry-waiting transport vehicles Va in the pre-junction section 41a with a larger cost C and the entry-waiting transport vehicles Va in the pre-junction section 41b with a smaller cost C, at a vehicle-number ratio corresponding to C1:C2.

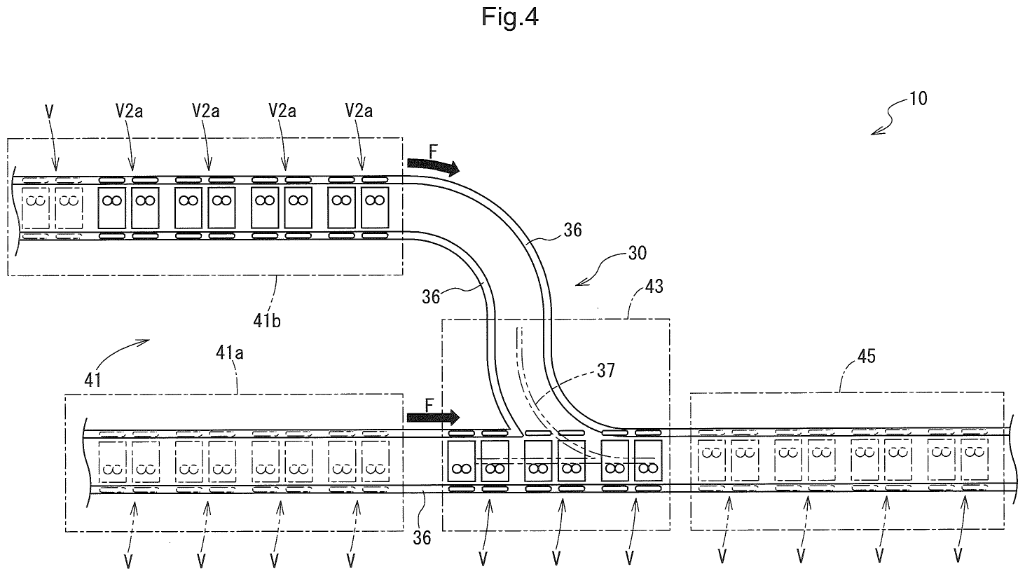

FIGS. 4 to 6 illustrate an example after the entry permission issuing process is performed but just before a subsequent entry permission issuing process is performed. Here, the entry-waiting transport vehicle Va in the pre-junction section 41 with a larger cost C is referred to as a first entry-waiting transport vehicle V1a, and the entry-waiting transport vehicle Va in the pre-junction section 41b with a smaller cost C is referred to as a second entry-waiting transport vehicle V2a. In the present embodiment, the entry permission is given to the first entry-waiting transport vehicles V1a and the second entry-waiting transport vehicles V2a at the ratio of C1:C2. In a case where the first cost C1 or the second cost C2 is not an integer, the first cost C1 or the second cost C2 may be rounded up, rounded down, or rounded off. As the ratio of the first cost C1 to the second cost C2 is larger, the magnification of the number of first entry-waiting transport vehicles V1a to receive the entry permission to the number of second entry-waiting transport vehicles V2a to receive the entry permission may be increased continuously or intermittently.

In a case where the control system 100 gives an entry permission to a plurality of first entry-waiting transport vehicles V1a, the control system 100 continuously gives the entry permission to all the first entry-waiting transport vehicles V1a targeted for the entry permission, and after that, the control system 100 gives an entry permission to the second entry-waiting transport vehicle V2a. Here, the number of first entry-waiting transport vehicles V1a continuously receiving the entry permission is referred to as a first entry permission number X1. In this configuration, the control system 100 continuously allows the first entry-waiting transport vehicles V1a corresponding to the first entry permission number X1 to enter the junction 43.

In a case where the control system 100 gives an entry permission to a plurality of second entry-waiting transport vehicles V2a, the control system 100 continuously gives the entry permission to all the second entry-waiting transport vehicles V2a targeted for the entry permission, and after that, the control system 100 gives an entry permission to the first entry-waiting transport vehicle V1a. Here, the number of second entry-waiting transport vehicles V2a continuously receiving the entry permission is referred to as a second entry permission number X2. In this configuration, the control system 100 continuously allows the second entry-waiting transport vehicles V2a corresponding to the second entry permission number X2 to enter the junction 43.

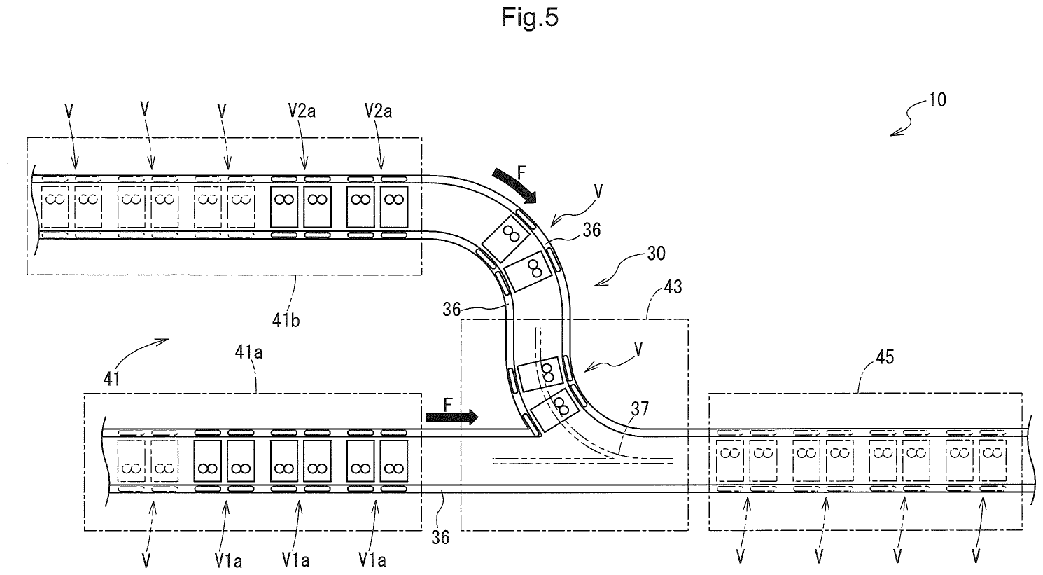

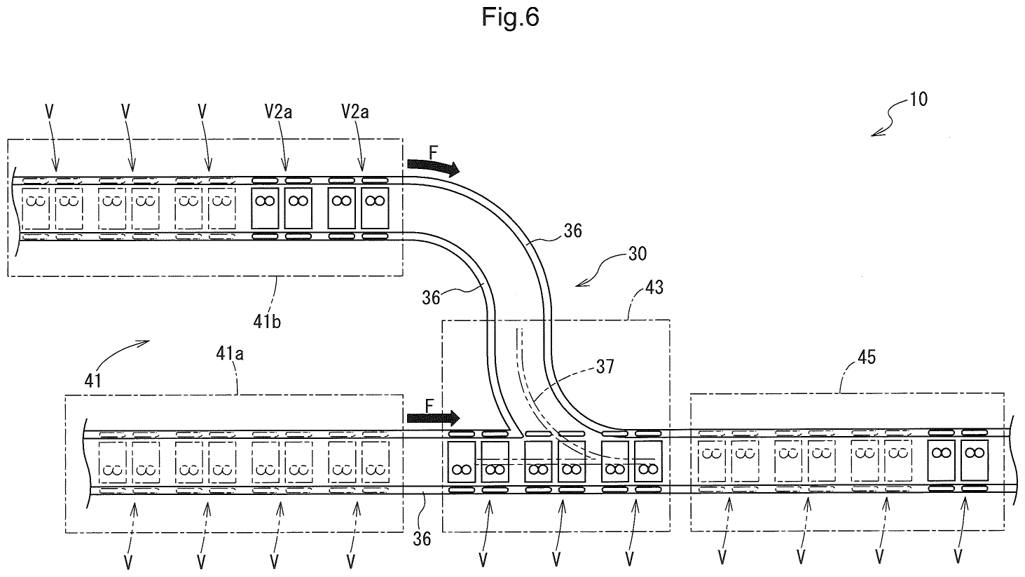

The ratio between the first entry permission number X1 and the second entry permission number X2 may be the same as C1:C2. The ratio between the first entry permission number X1 and the second entry permission number X2 may be different from C1:C2. For example, in the case of C1:C2=3:2, X1:X2 may be 3:2, or in the case of C1:C2=2:1, X1:X2 may be 3:2. In the example illustrated herein, three first entry-waiting transport vehicles V1a enter the junction 43 (the state in FIG. 4), two second entry-waiting transport vehicles V2a then enter the junction 43 (the state in FIG. 5), and after that, three first entry-waiting transport vehicles V1a enter the junction 43 (the state in FIG. 6).

In a case where the value of the first entry permission number X1 exceeds a predetermined entry upper limit Xa, the control system 100 performs the entry permission issuing process with the value of the first entry permission number X1 being replaced with the entry upper limit Xa. In a case where the value of the second entry permission number X2 exceeds the predetermined entry upper limit Xa, the control system 100 performs the entry permission issuing process with the value of the second entry permission number X2 being replaced with the entry upper limit Xa. Examples of the entry upper limit Xa include a value set for each pre-junction section 41, a value set for each post-junction section 45, a value set for each junction 43, and the like.

In a case where the value of the first entry permission number X1 is less than a predetermined entry lower limit Xb, the control system 100 performs the entry permission issuing process with the value of the first entry permission number X1 being replaced with the entry lower limit Xb. In a case where the value of the second entry permission number X2 is less than the predetermined entry lower limit Xb, the control system 100 performs the entry permission issuing process with the value of the second entry permission number X2 being replaced with the entry lower limit Xb. Examples of the entry lower limit Xb include a value set for each pre-junction section 41, a value set for each post-junction section 45, a value set for each junction 43, and the like.

FIG. 6 is a view to describe an entry-permittable number Xc. The control system 100 acquires information on the entry-permittable number Xc indicative of the number of transport vehicles V that can enter the post-junction section 45. The control system 100 may acquire the information on the entry-permittable number Xc periodically or every time the entry permission issuing process is performed.

Examples of the entry-permittable number Xc include a value obtained by subtracting a current value H12 of the number of transport vehicles V actually waiting in the post-junction section 45 from an upper limit H11 of the number of transport vehicles V allowable to wait in the post-junction section 45, a value set for each post-junction section 45, and the like. The entry-permittable number Xc may be acquired by an imaging device (not illustrated) configured to capture an image of the post-junction section 45 and image recognition, or the entry-permittable number Xc may be calculated based on values provided from various sensors, a set value, and the like. In the example illustrated herein, the entry-permittable number Xc is indicated by the number of transport vehicles V illustrated by an alternate long and two short dashes line in the post-junction section 45. For example, in the example illustrated in FIG. 6, the upper limit H11 of the number of transport vehicles V is four, and the current value H12 of the number of transport vehicles V is one, so that the entry-permittable number Xc is three.

In a case where the first entry permission number X1 exceeds the entry-permittable number Xc, the control system 100 performs the entry permission issuing process with the value of the first entry permission number X1 being replaced with a value equal to or less than the entry-permittable number Xc. In the present embodiment, in a case where the first entry permission number X1 exceeds the entry-permittable number Xc, the value of the first entry permission number X1 is replaced with the value of the entry-permittable number Xc.

In a case where the second entry permission number X2 exceeds the entry-permittable number Xc, the control system 100 performs the entry permission issuing process with the value of the second entry permission number X2 being replaced with a value equal to or less than the entry-permittable number Xc. In the present embodiment, in a case where the second entry permission number X2 exceeds the entry-permittable number Xc, the value of the second entry permission number X2 is replaced with the value of the entry-permittable number Xc.

After the control system 100 performs the entry permission issuing process and all the first entry-waiting transport vehicles V1a which correspond to the first entry permission number X1 and which have received the entry permission by the entry permission issuing process exit from the pre-junction section 41, the control system 100 performs a subsequent entry permission issuing process. Note that the subsequent entry permission issuing process may be performed before all the first entry-waiting transport vehicles V1a corresponding to the first entry permission number X1 exit from the junction 43. This allows the entry-waiting transport vehicles Va to efficiently enter the junction 43. The subsequent entry permission issuing process may be performed after all the first entry-waiting transport vehicles V1a corresponding to the first entry permission number X1 exit from the junction 43. This allows the entry-waiting transport vehicles Va to safely enter the junction 43. The subsequent entry permission issuing process may be performed after all the first entry-waiting transport vehicles V1a corresponding to the first entry permission number X1 enter the post-junction section 45.

After the control system 100 performs the entry permission issuing process and all the second entry-waiting transport vehicles V2a which correspond to the second entry permission number X2 and which have received the entry permission by the entry permission issuing process exit from the pre-junction section 41, the control system 100 performs a subsequent entry permission issuing process. Note that the subsequent entry permission issuing process may be performed before all the second entry-waiting transport vehicles V2a corresponding to the second entry permission number X2 exit from the junction 43. This allows the entry-waiting transport vehicles Va to efficiently enter the junction 43. The subsequent entry permission issuing process may be performed after all the second entry-waiting transport vehicles V2a corresponding to the second entry permission number X2 exit from the junction 43. This allows the entry-waiting transport vehicles Va to safely enter the junction 43. The subsequent entry permission issuing process may be performed after all the second entry-waiting transport vehicles V2a corresponding to the second entry permission number X2 enter the post-junction section 45.

Next will be described other embodiments of the article transport facility 10.
(1) The above embodiment has described, as an example, the configuration in which the pre-junction section 41 is a section determined in advance for each junction 43 and does not include other pre-junction sections 41. However, the present invention is not limited to such an example, and the pre-junction section 41 may include another pre-junction section 41 on the upstream side W2 from the pre-junction section 41, the junction 43, the post-junction section 45, a station, a curve section, and the like, for example.
(2) The above embodiment has described, as an example, the configuration in which the post-junction section 45 is a section determined in advance for each junction 43 and does not include other post-junction sections 45. However, the present invention is not limited to such an example, and the post-junction section 45 may include the pre-junction section 41 on the downstream side W1 from the post-junction section 45, the junction 43, another post-junction section 45, a station, a curve section, and the like, for example.
(3) The above embodiment has described, as an example, the configuration in which, in a case where the control system 100 gives an entry permission to a plurality of first entry-waiting transport vehicles V1a, the control system 100 continuously gives the entry permission to all the first entry-waiting transport vehicles V1a targeted for the entry permission, and then, the control system 100 gives an entry permission to the second entry-waiting transport vehicle V2a. However, the present invention is not limited to such an example, and the control system 100 may intermittently give an entry permission to all the first entry-waiting transport vehicles V1a targeted for the entry permission, for example. For example, the control system 100 may give an entry permission to five first entry-waiting transport vehicles V1a at an interval, and the control system 100 may give an entry permission to three or less second entry-waiting transport vehicles V2a during the interval.
(4) The above embodiment has described, as an example, the configuration in which the control system 100 gives an entry permission to the first entry-waiting transport vehicles V1a and the second entry-waiting transport vehicles V2a at a vehicle-number ratio corresponding to C1:C2. However, the present invention is not limited to such an example, and the control system 100 may always give an entry permission to the first entry-waiting transport vehicles V1a the number of which is 1.5 times the number of second entry-waiting transport vehicles V2a, for example. For example, in a case where the difference between the number of first entry-waiting transport vehicles V1a and the number of second entry-waiting transport vehicles V2a is a predetermined value or less, the first entry-waiting transport vehicles V1a may be prioritized.
(5) The above embodiment has described, as an example, the configuration in which the cost C is calculated based on at least one or the like of the length H1, the upper limit H2 for the number of transport vehicles V, the upper limit H3 of traveling speed, the average value H4 of traveling speeds, the current value H5 of the number of transport vehicles V, and the predicted value H6 of the number of transport vehicles V. However, the present invention is not limited to such an example, and some of the length H1, the upper limit H2 for the number of transport vehicles V, the upper limit H3 of traveling speed, the average value H4 of traveling speeds, the current value H5 of the number of transport vehicles V, and the predicted value H6 of the number of transport vehicles V may be omitted in advance in the calculation of the cost C, for example. For example, the cost C may be calculated based on at least one or the like of the length H1, the upper limit H2 for the number of transport vehicles V, the upper limit H3 of traveling speed, the average value H4 of traveling speeds, and the predicted value H6 of the number of transport vehicles V. For example, the cost C may be calculated based on at least one or the like of the length H1, the upper limit H3 of traveling speed, and the average value H4 of traveling speeds. For example, the cost C may be calculated based on at least one or the like of the length H1, the upper limit H2 for the number of transport vehicles V, and the predicted value H6 of the number of transport vehicles V.
(6) The above embodiment has described, as an example, the configuration in which only two pre-junction sections 41 are merged into only one post-junction section 45 at the junction 43. However, the present invention is not limited to such an example and, for example, the branch 47 branching to a path different from the post-junction section 45 may be between the pre-junction section 41 and the junction 43 or between the junction 43 and the post-junction section 45, and the transport vehicle V waiting for entering the branch 47 may also wait at the pre-junction section 41. In such a configuration in which the transport vehicle V waiting for entering the branch 47 also waits at the pre-junction section 41, the branch may be considered to be included in the junction 43, and the number of transport vehicles V waiting for entering the branch 47 may be included in the number of entry-waiting transport vehicles Va waiting for entering the junction 43. Three or more pre-junction sections 41 may be merged into one post-junction section 45 at the junction 43, and the entry permission issuing process using the cost C may be performed on at least two pre-junction sections 41 among the three or more pre-junction sections 41.
(7) Note that the configurations disclosed in the above embodiment can be applied in combination with the configurations disclosed in other embodiments (including combinations of the embodiments described as the other embodiments) as long as no inconsistency occurs. In terms of other configurations, the embodiment disclosed in the present specification is also just an example in all respects. Accordingly, various modifications can be made appropriately as far as it does not deviate from the scope of this disclosure.

The following describes an article transport facility according to this disclosure.

As one aspect, an article transport facility includes: a plurality of transport vehicles each configured to move along a predetermined path and transport an article; and a control system configured to control the plurality of transport vehicles. The path includes a junction at which two pre-junction sections are merged into one post-junction section. The control system is configured to perform an entry permission issuing process of giving an entry permission to allow the plurality of transport vehicles to enter the junction, based on a cost calculated as a factor influencing a travel time of the transport vehicles in each of the two pre-junction sections which cost increases as the travel time is longer, in such a manner as to give the entry permission to more entry-waiting transport vehicles in a first pre-junction section for which the cost is larger out of the two pre-junction sections than in a second pre-junction section for which the cost is smaller out of the two pre-junction sections, the entry-waiting transport vehicles being transport vehicles waiting for entering the junction.

With this configuration, a larger number of transport vehicles in a pre-junction section that requires a longer travel time for the transport vehicles out of the two pre-junction sections preferentially receive the entry permission to enter the junction, thereby making it possible to reduce inequality in the number of entry-waiting transport vehicles between the two pre-junction sections. This can easily reduce such a possibility that the number of entry-waiting transport vehicles in either of the pre-junction sections is too large, and this influences the movement of other transport vehicles in a section on the upstream side from the pre-junction section. This accordingly makes it possible to restrain the occurrence of a traffic jam in the section on the upstream side from the pre-junction section.

As one aspect, the control system is configured to give the entry permission to the entry-waiting transport vehicles in the first pre-junction section and the entry-waiting transport vehicles in the second pre-junction section at a vehicle-number ratio corresponding to C1:C2, where C1 is a first cost as the larger cost, and C2 is a second cost as the smaller cost.

With this configuration, the entry permission to enter the junction can be given to the entry-waiting transport vehicles in each of the pre-junction sections at the vehicle-number ratio corresponding to the ratio of cost between the two pre-junction sections. This accordingly makes it possible to more appropriately reduce inequality in the number of entry-waiting transport vehicles between the two pre-junction sections.

As one aspect, the control system calculates the cost based on at least one of a length of a corresponding pre-junction section, an upper limit for the number of transport vehicles allowable to wait in the corresponding pre-junction section, an upper limit of traveling speed for the transport vehicles in the corresponding pre-junction section, an average value of traveling speeds of the transport vehicles in the corresponding pre-junction section, the number of transport vehicles currently in the corresponding pre-junction section, or the number of transport vehicles expected in the corresponding pre-junction section.

With this configuration, the cost of each of the pre-junction sections can be calculated appropriately. Accordingly, in a case where the entry permission issuing process is performed, the entry permission can be more suitably given to the entry-waiting transport vehicles in each of the pre-junction section.

As one aspect, the entry-waiting transport vehicles in the pre-junction section with a larger cost is defined as first entry-waiting transport vehicles, and the entry-waiting transport vehicles in the pre-junction section with a smaller cost are defined as second entry-waiting transport vehicles. In a case where the control system gives the entry permission to a plurality of first entry-waiting transport vehicles, the control system continuously gives the entry permission to all the first entry-waiting transport vehicles targeted for the entry permission, and after that, the control system gives the entry permission to the second entry-waiting transport vehicles.

With this configuration, a plurality of entry-waiting transport vehicles in either

of the pre-junction sections is continuously allowed to enter the junction, and then, entry-waiting transport vehicles in the other of the pre-junction sections are allowed to enter the junction. Accordingly, in comparison with a case where the entry-waiting transport vehicles in two pre-junction sections are alternately allowed to enter the junction, the number of transport vehicles to pass the junction per unit time can be easily increased. This makes it possible to easily increase the efficiency of the movement of the transport vehicles.

The article transport facility according to this disclosure should be able to achieve at least one of the above effects. The technical feature of the article transport facility according to this disclosure is also applicable to an article transport method and an article transport program.

What is claimed is:

1. An article transport facility, comprising:
a plurality of transport vehicles each configured to move along a predetermined path and transport an article; and
a control system configured to control the plurality of transport vehicles, and wherein:
the path comprises a junction at which two pre-junction sections are merged into one post-junction section, and
the control system is configured to perform an entry permission issuing process of giving an entry permission to allow the plurality of transport vehicles to enter the junction based on a cost calculated as a factor influencing a travel time of the transport vehicles in each of the two pre-junction sections, which cost increases as the travel time is longer, and in such a manner as to give the entry permission to more entry-waiting transport vehicles in a first pre-junction section for which the cost is larger out of the two pre-junction sections than in a second pre-junction section for which the cost is smaller out of the two pre-junction sections, the entry-waiting transport vehicles comprising transport vehicles waiting for entering the junction.

2. The article transport facility according to claim 1, wherein:
the control system gives the entry permission to the entry-waiting transport vehicles in the first pre-junction section and the entry-waiting transport vehicles in the second pre-junction section at a vehicle-number ratio corresponding to C1:C2, where C1 is a first cost as the larger cost, and C2 is a second cost as the smaller cost.

3. The article transport facility according to claim 1, wherein:
the control system calculates the cost based on at least one of:
a length of a corresponding pre-junction section,
an upper limit for the number of transport vehicles allowable to wait in the corresponding pre-junction section,
an upper limit of traveling speed for the transport vehicles in the corresponding pre-junction section,
an average value of traveling speeds of the transport vehicles in the corresponding pre-junction section,
the number of transport vehicles currently in the corresponding pre-junction section, or
the number of transport vehicles expected in the corresponding pre-junction section.
